(19) United States
(12) Patent Application Publication
(10) Pub. No.: US 2026/0068072 A1
(43) Pub. Date: Mar. 5, 2026

(54) CABINET STRUCTURE

(71) Applicant: Lenovo (Beijing) Limited, Beijing (CN)

(72) Inventor: Na YIN, Beijing (CN)

(21) Appl. No.: 19/304,888

(22) Filed: Aug. 20, 2025

(30) Foreign Application Priority Data
Aug. 30, 2024 (CN) 202411216520.6

(51) Int. Cl. H05K 7/14; H05K 7/20

(52) U.S. Cl. CPC H05K 7/1492; H05K 7/20781

(57) ABSTRACT

A cabinet structure includes: a cabinet body, defining a first cavity to receive servers; an expansion assembly, contacting the cabinet body and defining a second cavity in communication with the first cavity; and a water-cooling door, to remove heat from the first and second cavities through heat transfer.

### RELATED APPLICATION(S)

This application claims priority to Chinese Patent Application No. 2024112165206 filed with China Intellectual Property Administration on Aug. 30, 2024, which is incorporated herein by reference in entirety.

### FIELD OF THE TECHNOLOGY

The present disclosure relates to a technical field of cabinet equipment, and in particular to a cabinet structure.

### BACKGROUND

Water-cooled cabinet solutions are gaining market popularity. However, this approach may result in an increasing number of pipes and equipment lines within the cabinet. Limited cabinet space may result in a narrow bending radius for pipes, necessitating the addition of cabinet expansion structures to facilitate cable routing through openings.

Because the openings in these expansion structures may need to accommodate a large number of cables, the openings are designed to be large. However, overly large openings may allow heat to escape from the cabinet, affecting the temperature of the computer room.

### SUMMARY

In one aspect, the present disclosure provides a cabinet structure. The cabinet structure includes a cabinet body, defining a first cavity to receive servers; an expansion assembly, contacting the cabinet body and defining a second cavity in communication with the first cavity; and a water-cooling door, to remove heat from the first and second cavities through heat transfer.

In another aspect, the present disclosure provides a method of forming a cabinet structure. The method includes: providing a cabinet body, an expansion assembly, and a water-cooling door, wherein the cabinet body is configured to define a first cavity to receive servers, the expansion assembly is configured to contact the cabinet body and define a second cavity in communication with the first cavity, and the water-cooling door is configured to remove heat from the first and second cavities through heat transfer.

In yet another aspect, the present disclosure provides a cabinet structure. The cabinet structure includes: a cabinet body, defining a first cavity to receive servers; an expansion assembly, contacting the cabinet body and defining a second cavity in communication with the first cavity; a water-cooling door, to remove heat from the first and second cavities through heat transfer; and a connecting assembly, contacting the cabinet body, the expansion assembly, and the water-cooling door.

### BRIEF DESCRIPTION OF THE DRAWINGS

To illustrate the technical solutions in certain embodiments of the present disclosure, the following briefly describes the drawings used in certain embodiments. The drawings described below represent only certain embodiments of the present disclosure. Persons skilled in the technical field may derive other drawings based on these drawings without inventive effort.

FIG. 1 is a schematic diagram of a cabinet structure provided in certain embodiments of the present disclosure;

FIG. 2 is a schematic diagram of a cabinet structure provided in certain embodiments of the present disclosure;

FIG. 3 is a schematic diagram of an expansion assembly provided in certain embodiments of the present disclosure;

FIG. 4 is a schematic diagram of a partial structure of a first opening structure provided in certain embodiments of the present disclosure;

FIG. 5 is a schematic diagram of a partial structure of a first opening structure provided in certain embodiments of the present disclosure;

FIG. 6 is a schematic diagram of a partial structure of a side panel of an expansion assembly provided in certain embodiments of the present disclosure;

FIG. 7 is a schematic diagram of a partial structure of a second opening structure provided in certain embodiments of the present disclosure;

FIG. 8 is a schematic diagram of a partial structure of a top plate of an expansion assembly provided in certain embodiments an embodiment of the present disclosure;

FIG. 9 is a schematic diagram of a first connector provided in certain embodiments of the present disclosure;

FIG. 10 is a schematic diagram of a second connector provided in certain embodiments of the present disclosure;

FIG. 11 is a schematic diagram of an expansion assembly and functional components provided in certain embodiments of the present disclosure;

FIG. 12 is a schematic diagram of an expansion assembly provided in certain embodiments of the present disclosure;

FIG. 13 is a schematic diagram of an expansion assembly provided in certain embodiments of the present disclosure;

FIG. 14 is a schematic diagram of a second positioning component provided in certain embodiments of the present disclosure; and

FIG. 15 is a schematic diagram of a third positioning component provided in certain embodiments of the present disclosure.

### DETAILED DESCRIPTION

The present disclosure in certain embodiments discloses a cabinet structure to reduce heat dissipation.

The following, combined with the accompanying drawings, describes the technical solutions in certain embodiment of the present disclosure. The described embodiments represent only a portion of certain embodiments of the present disclosure, not all of them. Other embodiments derived by persons of ordinary skill in the technical field based on certain embodiments of the present disclosure without inventive effort are within the scope of protection of the present disclosure.

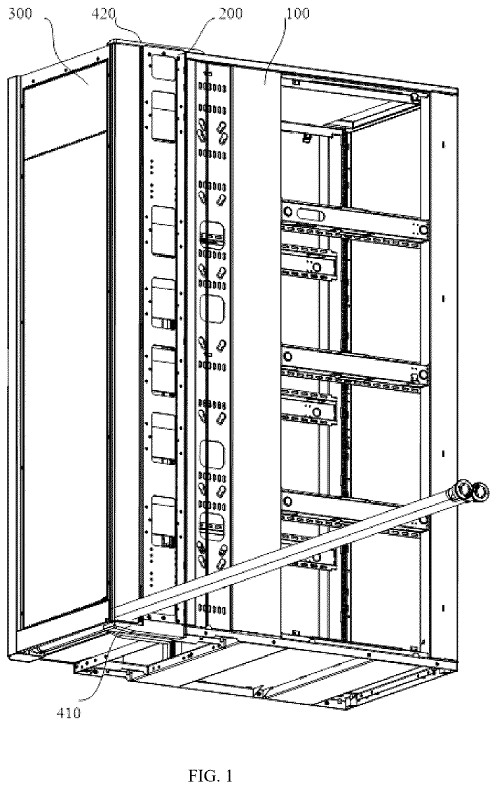

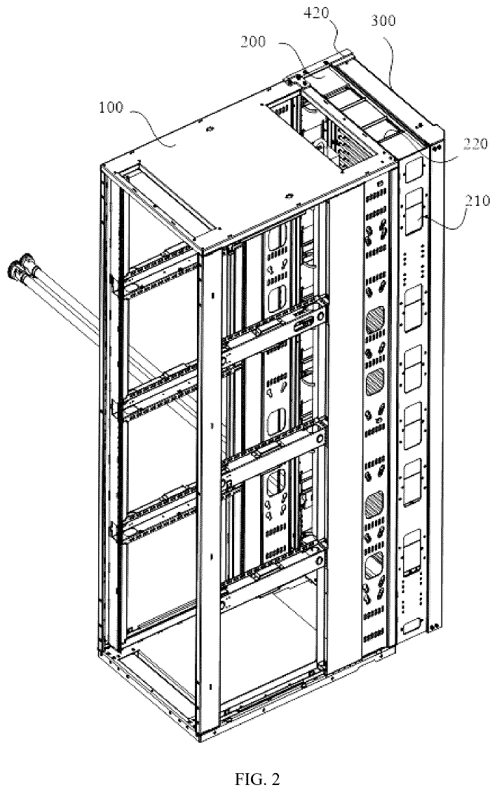

As shown in FIGS. 1, 2, and 3, certain embodiments of the present disclosure provide a cabinet structure including a cabinet body 100, an expansion assembly 200, and a water-cooling door 300.

The cabinet body 100 has a first cavity for accommodating servers; the expansion assembly 200 is connected to the cabinet body 100 and has a second cavity communicating with the first cavity. The connection between the expansion assembly 200 and the cabinet body 100 allows the first and second cavities to communicate, increasing the internal space of the cabinet structure and facilitating proper bending and accommodation of pipes and cables within the cabinet structure.

The water-cooling door 300 removes heat from the first and second cavities through heat transfer and is located on the side of the expansion assembly 200 facing away from the cabinet body 100. The expansion assembly 200 functions to provide expansion space (the second cavity), and its structural strength (load-bearing capacity) may be relatively low. Among them, the factors that affect the structural strength of the expansion assembly 200 may include the open hole structure of the expansion assembly 200. If the water-cooled door 300 is directly connected to the expansion assembly 200, there may be a situation where the expansion assembly 200 cannot meet the demand for carrying the water-cooled door 300. Therefore, one end of the connecting assembly is connected to the cabinet body 100, and the other end of the connecting assembly is located on the side of the expansion assembly 200 facing away from the cabinet body 100 and has a connecting portion, and the water-cooled door 300 is located on the side of the expansion assembly 200 facing away from the cabinet body 100 and has a mating portion that is adapted to be connected to the connecting portion. Through the above-mentioned arrangement, the connecting assembly may connect the cabinet body 100 and the water-cooled door 300, and the cabinet body 100 may provide support for the water-cooled door 300 through the connecting assembly, avoiding the situation where the water-cooled door 300 is supported only by the expansion assembly 200.

Furthermore, the expansion assembly 200 includes an opening for routing cables. This allows for connections between devices inside and outside the cabinet structure. Because the water-cooled door 300 may remove heat from the first and second cavities through heat transfer, the heat exchange path between the water-cooled door 300 and heat-generating devices (such as servers) within the cabinet structure passes through at least the second cavity. Since the opening area of the opening is adjustable, the area may be adjusted based on the actual number of cables passing through the opening. For example, when no cables pass through the opening, the opening area may be adjusted to its minimum value (including closing all openings to achieve a zero opening area). When a small number of cables pass through the opening, the opening area may be adjusted to align with the number of cables passing through the opening. This helps reduce the hollow area of the opening that is not filled with cables and extends through the inside and outside of the cabinet (between the second cavity of the expansion assembly 200 and the outside of the cabinet), thereby reducing heat leakage from within the cabinet structure and minimizing the impact on the overall temperature rise in the computer room.

The above arrangement facilitates the control of computer room issues, facilitating data center acceptance and ensuring the normal operation of equipment within the room. Furthermore, by adjusting the opening area of the opening structure, the expansion assembly 200 improves its ability to shield the interior of the cabinet structure, reducing the likelihood of personnel observing or accessing equipment (such as servers or hard drives) within the cabinet structure through the opening structure.

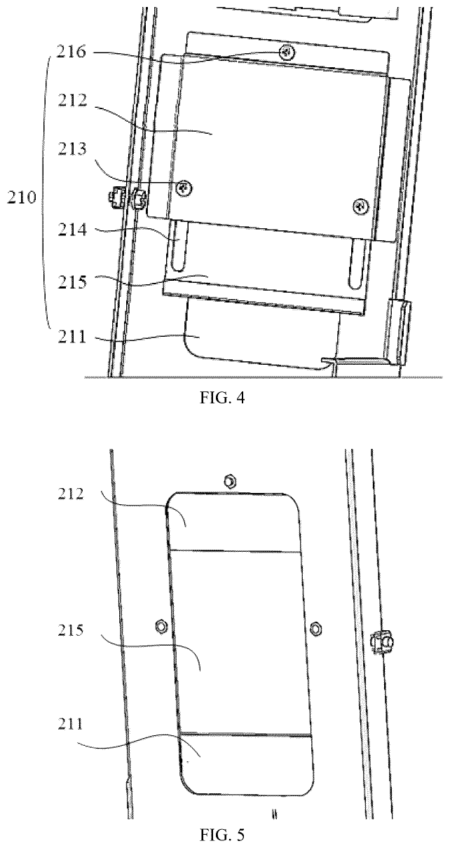

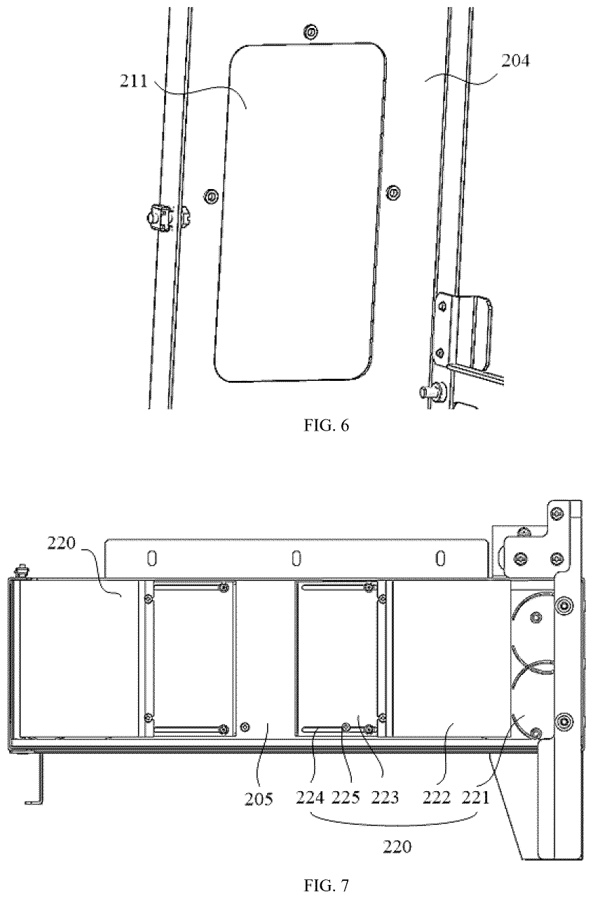

As shown in FIGS. 4, 5, and 6, in certain embodiments of the present disclosure, the opening structure includes a first opening structure 210 disposed on a side panel 204 of the expansion assembly 200. The first opening structure 210 includes a first opening 211 and a first shielding group. The first opening 211 extends through the side panel 204 of the expansion assembly 200. The first shielding group is movably connected to the side panel 204 of the expansion assembly 200 and may at least partially shield the first opening 211. The unshielded portion of the first opening 211 is accessible for cables to pass through. When the first shielding group and the side panel 204 of the expansion assembly 200 are relatively moved and positioned, the area of the unshielded portion of the first opening 211 is the opening area after the first opening structure 210 is adjusted.

The first opening structures 210 may be multiple in number and may be arranged along the vertical direction of the side panels 204 of the expansion assembly 200 (for example, the alignment of the top panel 205 and bottom panel of the expansion assembly 200).

In certain embodiments, the expansion assembly 200 includes two side panels 204 connecting the top panel 205 and the bottom panel. The two side panels 204, the top panel 205, and the bottom panel form a second cavity. Both side panels 204 may have first opening structures 210. In certain embodiments, the first opening structures 210 provided on the two side panels 204 may be arranged symmetrically in the horizontal direction to allow cables to pass through both sides of the cabinet structure (where the two side panels 204 are located). This allows for selection of the appropriate first opening structure 210 to suit the use of the cabinet structure.

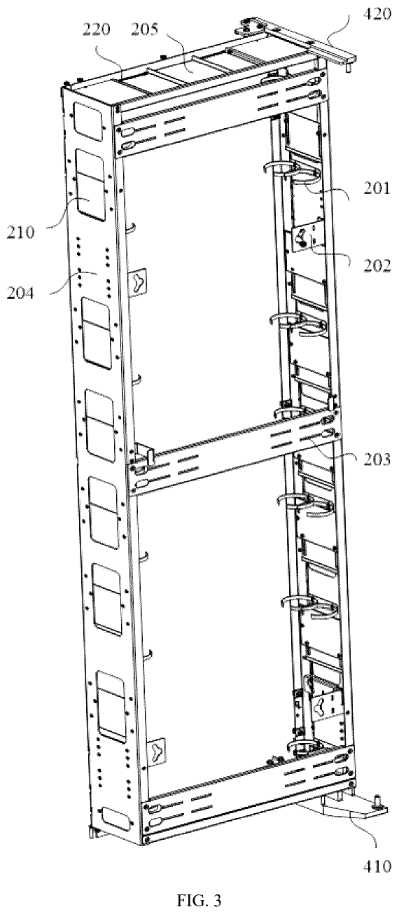

As shown in FIG. 3, to enhance the structural stability of the expansion assembly 200, the expansion assembly 200 also includes a plurality of support frames 203 connecting the two side panels 204. The support frames 203 are arranged along the vertical direction of the expansion assembly 200.

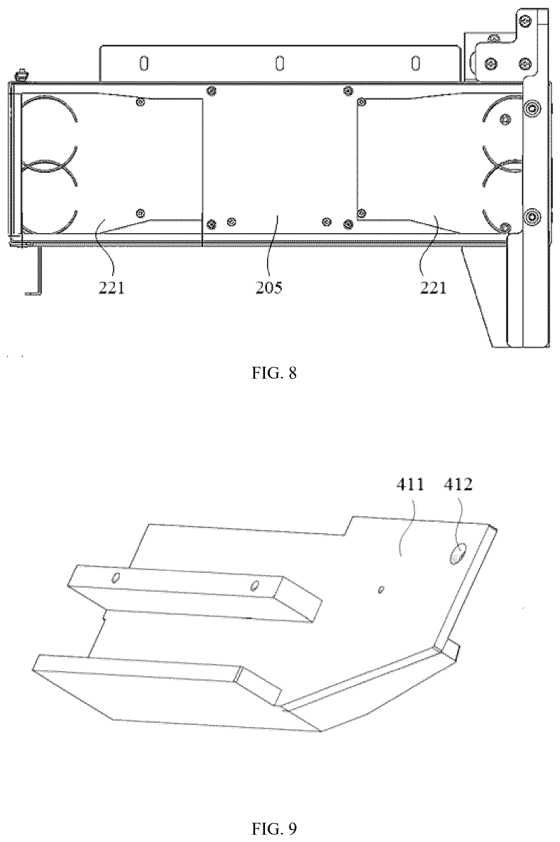

In certain embodiments, as shown in FIGS. 7 and 8, the opening structure may also include a second opening structure 220 provided on the top panel 205 of the expansion assembly 200. The second opening structure 220 includes a second opening 221 and a second shielding group. The second opening 221 extends through the top panel 205 of the expansion assembly 200. The second shielding group is movably connected to the top panel 205 of the expansion assembly 200 and may at least partially shield the second opening 221. The unshielded portion of the second opening 221 allows cables to pass through. When the second shielding group and the top panel 205 of the expansion assembly 200 are relatively moved and positioned, the area of the unshielded portion of the second opening 221 represents the adjusted opening area of the second opening structure 220.

In certain embodiments, the top panel 205 has two ends connected to the two side panels 204, respectively. The second opening structure 220 may be provided at both ends of the top panel 205 to facilitate selection of the appropriate second opening structure 220 based on the cabinet structure.

The use of the cabinet structure may include the layout of the equipment within the cabinet structure and the placement of the cabinet structure within the computer room.

In certain embodiments, the first opening structure 210 provided on the side panel 204 of the expansion assembly 200 and the second opening structure 220 provided on the top panel 205 of the expansion assembly 200 may be used to allow cables with different functions to pass through.

The first shielding group includes a first shielding plate 212, which is detachably connected to the side panel 204 of the expansion assembly 200. The first shielding plate 212 may at least partially shield the first opening 211. That is, the opening area of the first opening structure 210 may be adjusted by attaching and detaching the first shielding plate 212 to the side panel 204 of the expansion assembly 200.

In certain embodiments, the first shielding assembly may include a first sliding plate 215, which is slidably connected to the side panel 204 of the expansion assembly 200. Sliding the first sliding plate 215 may adjust the area of the first opening 211 shielded by the first sliding plate 215. That is, the opening area of the first opening structure 210 may be adjusted by sliding the first sliding plate 215 to the side panel 204 of the expansion assembly 200.

To increase the flexibility of adjusting the opening area of the first opening structure 210, the first shielding group includes a first shielding plate 212 and a first sliding plate 215. The area of the first opening 211 shielded by the first shielding plate 212 may be an infrequently used area. For example, when the first opening structure 210 is to pass a maximum number of cables, the portion of the first opening 211 shielded by the first shielding plate 212 and the first sliding plate 215 may need to be entirely unshielded. In this state, the first shielding plate 212 may be directly removed from the side panel 204 of the expansion assembly 200. The area where the first sliding plate 215 shields the first opening 211 may require frequent adjustment. For example, when the first opening structure 210 is to pass some cables, the first shielding plate 212 is maintained in contact with the side panel 204 of the expansion assembly 200. This allows the area where the first shielding plate 212 shields the first opening 211 to be less frequently used. The area of the first opening 211 not shielded by the first shielding plate 212 also includes the area that may be shielded by the first sliding plate 215. The sliding position of the first sliding plate 215 on the side panel 204 of the expansion assembly 200 is adjusted based on the number of cables passing through the first opening structure 210, thereby adjusting the opening area of the first opening structure 210 to align with the number of cables passing through the first opening structure 210.

In the cabinet structure in certain embodiments of the present disclosure, the first opening structure 210 is arranged on the side panel 204 of the expansion assembly 200. When the size of the first opening 211 is too large, people outside the cabinet structure may be able to remove the equipment from inside the cabinet structure through the first opening 211, which may easily cause economic losses and pose a safety hazard.

In certain embodiments, the first opening structure 210 may be provided with a restricting structure that limits the movement of the first shielding group relative to the side panel 204 of the expansion assembly 200. This restricting structure may only be operated from within the cabinet structure to restrict the movement of the first shielding group relative to the side panel 204 of the expansion assembly 200.

In certain embodiments, the first shielding group includes a first shielding plate 212, a first sliding plate 215, and a mating connector 213; the mating connector 213 serves as the restricting structure.

In certain embodiments, the mating connector 213 may be operated from within the expansion assembly 200 to achieve a detachable connection between the first shielding plate 212 and the side panel 204 of the expansion assembly 200.

The first sliding plate 215 may have a first sliding structure 214 that may slide and cooperate with the mating connector 213, and the mating connector 213 may be switched between the first state and the second state by internal operation of the expansion assembly 200; in the first state, the mating connector 213 may limit the sliding of the mating connector 213 and the first sliding structure 214, so that the first sliding plate 215 is locked on the side panel 204 of the expansion assembly 200; in the second state, the mating connector 213 slides and cooperates with the first sliding structure 214, so that the first sliding plate 215 may slide relative to the side panel 204 of the expansion assembly 200.

The mating connector 213 that enables the detachable connection between the first shielding plate 212 and the side panel 204 of the expansion assembly 200 and the mating connector 213 that enables the switch between the first and second states may be the same mating connector 213 or different mating connectors 213.

In certain embodiments, the mating connector 213 may be a connecting bolt, and the first sliding structure 214 may be a strip-shaped hole. The connecting bolt passes through the mounting hole of the first shielding plate 212 and the first sliding structure 214 and connects to the side panel 204 of the expansion assembly 200. The head of the connecting bolt is located inside the expansion assembly (the second cavity). An operator may operate the head of the connecting bolt from inside the expansion assembly to tighten the connecting bolt, thereby adjusting the distance between the head of the connecting bolt and the side panel 204 of the expansion assembly 200.

The first shielding plate 212 and the first sliding plate 215 are located between the head of the connecting bolt and the side panel 204 of the expansion assembly 200. When the connecting bolt is tightened, the head of the connecting bolt applies pressure to the side panel 204 of the expansion assembly 200, positioning the first shielding plate 212 and the first sliding plate 215 relative to the side panel 204 of the expansion assembly 200. This causes the mating connector 213 to switch to the first position, locking the first sliding plate 215 to the side panel of the expansion assembly 200. When the connecting bolt is loosened, the connecting bolt connects to the side panel 204 of the expansion assembly 200, maintaining the connection between the first shielding plate 212 and the side panel 204 of the expansion assembly 200. This causes the mating connector 213 to switch to the second position, allowing the first sliding plate 215 to slide relative to the side panel of the expansion assembly. When the connecting bolt is separated from the side panel 204 of the expansion assembly 200, the first shielding plate 212 and the first sliding plate 215 may be separated from the side panel 204 of the expansion assembly 200.

The head of the connecting bolt may be cross or flat, so as to match the corresponding screwdriver. The connecting bolt may also be set as a hand-tightening bolt, with the head of the connecting bolt being a hand-tightening handle.

Nuts may be provided on the outside of the side panels 204 of the expansion assembly 200 to engage with the connecting bolts; threaded holes may also be provided on the side panels 204 of the expansion assembly 200 to engage with the connecting bolts.

To enhance the connection stability of the first shielding plate 212, auxiliary connectors 216 (such as bolts) may be provided, for connecting the first shielding plate 212 to the side panels 204 of the expansion assembly 200.

In certain embodiments, the restricting structure may be provided in other configurations, such as a shielding member (such as a positioning bolt) provided on the inside of the side panels 204 of the expansion assembly 200 to limit contact with the edge of the first sliding plate 215, or a fastening member for applying pressure to the first shielding plate 212 or the first sliding plate 215 toward the side panels 204 of the expansion assembly 200.

Due to the principle that air heats up and cools down, heat within the cabinet structure is more likely to escape through the second opening structure 220 provided on the top panel 205 of the expansion assembly 200. In order to further reduce the heat overflow, the second shielding group includes a second sliding plate 223 and a flexible shielding component 222 (as shown in FIGS. 7 and 8). The second sliding plate 223 may be slidably connected to the top panel 205 of the expansion assembly 200; the flexible shielding component 222 is connected to the second sliding plate 223, and the sliding of the second sliding plate 223 may adjust the area of the second opening 221 shielded by the flexible shielding component 222. The flexible shielding component 222 may shield the gap of the second opening 221 through flexible deformation. The gap of the second opening 221 includes at least one of a first gap between multiple cables passing through the second opening 221, a second gap between the cable passing through the second opening 221 and the second sliding plate 223, and a third gap between the cable passing through the second opening 221 and the hole wall of the second opening 221.

In certain embodiments, the flexible shielding component 222 is a brush. The brush portion of the brush includes multiple fiber strips. These fiber strips may separate and merge relative to each other and may also bend, covering any one of the three aforementioned gaps (the first gap, the second gap, and the third gap). The flexible shielding component 222 may be configured as a cotton sheet or rubber block.

In certain embodiments, as shown in FIG. 7, the top panel 205 of the expansion assembly 200 is provided with second opening structures 220 at both ends, and the two second opening structures 220 are symmetrically arranged. The second sliding plate 223 has a second sliding structure 224. The sliding connector 225 is fixedly connected to the top panel 205 and slidably engages with the second sliding structure 224.

In certain embodiments, the sliding connector 225 is a connecting bolt, and the second sliding structure 224 is a strip-shaped hole extending in the sliding direction of the second sliding plate 223. The sliding connector 225 passes through the second sliding structure 224 and is connected to the top panel 205. In certain embodiments, the sliding of the second sliding plate 223 may be restricted by tightening the sliding connector 225 (connecting bolt).

In certain embodiments, as shown in FIG. 9, the connecting assembly includes a first connector 410. The first connector 410 has a support surface 411 for supporting the water-cooled door 300. The bottom surface of the water-cooled door 300 may contact the support surface 411. The first connector 410 may support the water-cooled door 300, providing further support for the water-cooled door 300 and further enhancing its support.

In certain embodiments, the first connector 410 is a hinged member, meaning that the water-cooled door 300 may be rotatably connected to the first connector 410. The first connector 410 has a rotational connection hole 412. The connecting portion of the first connector 410 is the first connection portion. The rotational connection hole 412 may be rotatably connected to the water-cooled door 300 via a first connection portion (such as a rotating shaft or bearing).

In certain embodiments, the connecting assembly includes a second connector 420, which is positioned higher than the first connector 410; one side of the water-cooled door 300 has a first matching portion and a second matching portion, the first matching portion is adapted to be connected to the first connector 410, and the second matching portion is adapted to be connected to the second connector 420.

The connecting portion of the second connector 420 is the second connecting portion. In certain embodiments, the second connector 420 is a hinged member, meaning that the water-cooled door 300 is rotatably connected to the second connector 420. The second connecting portion of the second connector 420 (such as a rotating shaft and bearing) is rotatably connected to the water-cooled door 300.

The first and second connecting portions are coaxially arranged.

To further enhance support for the water-cooled door 300, in certain embodiments, the connecting assembly is connected to the expansion assembly 200. In certain embodiments, the first connector 410 is located at the bottom of the cabinet structure, and the second connector 420 is located at the top of the cabinet structure.

In certain embodiments, the first connector 410 has a first surface, which includes a first region, a second region, and a third region arranged in sequence. The first region is connected to the bottom surface of the cabinet body 100, the second region is connected to the bottom surface of the expansion module 200, and the third region has a first connecting portion.

By sequentially arranging the first, second, and third regions, the first connector 410 may sequentially connect the cabinet body 100, the expansion module 200, and the water-cooling door 300, thereby improving support for the water-cooling door 300.

In certain embodiments, the first, second, and third regions are located on the first surface of the first connector 410. When the cabinet body 100, the expansion assembly 200, and the water-cooled door 300 are positioned relative to each other (for example, when the cabinet body 100 and the expansion assembly 200 are bolted together, or when the water-cooled door 300 is positioned to mate with the expansion assembly 200), the first surface of the first connector 410 may be moved toward the cabinet body 100, the expansion assembly 200, and the water-cooled door 300 to achieve respective correspondence between the different regions on the first surface and the cabinet body 100, the expansion assembly 200, and the water-cooled door 300, thereby facilitating the connection of the first connector 410 to the cabinet body 100, the expansion assembly 200, and the water-cooled door 300. That is, the same surface of the first connector 410 is connected to the cabinet body 100, the expansion assembly 200, and the water-cooled door 300. The first surface may be either a flat surface or a curved surface. Of course, different surfaces of the first connector 410 may also be connected to the cabinet body 100, the expansion assembly 200, and the water-cooling door 300, respectively.

The second connector 420 has a second surface, which includes a fourth region, a fifth region, and a sixth region arranged in sequence. The fourth region is connected to the top surface of the cabinet body 100, the fifth region is connected to the top surface of the expansion assembly 200, and the sixth region has a second connecting portion.

In certain embodiments, the sequential arrangement of the fourth, fifth, and sixth regions allows the second connector 420 to connect to the cabinet body 100, the expansion assembly 200, and the water-cooled door 300, thereby enhancing support for the water-cooled door 300.

In certain embodiments, the fourth, fifth, and sixth regions are all located on the second surface of the second connector 420. When the cabinet body 100, the expansion assembly 200, and the water-cooled door 300 are positioned relative to each other (for example, when the cabinet body 100 and the expansion assembly 200 are bolted together, or when the water-cooled door 300 is positioned to align with the expansion assembly 200), the second connector 420 may be moved toward the cabinet body 100, the expansion assembly 200, and the water-cooled door 300 to align different regions on the second surface with the cabinet body 100, the expansion assembly 200, and the water-cooled door 300, thereby facilitating the connection of the second connector 420 to the cabinet body 100, the expansion assembly 200, and the water-cooled door 300. That is, the same surface of the second connector 420 is connected to the cabinet body 100, the expansion assembly 200 and the water-cooling door 300. The second surface may be a flat surface or a curved surface.

In certain embodiments, different surfaces of the second connector 420 may be connected to the cabinet body 100, the expansion assembly 200, and the water-cooling door 300, respectively.

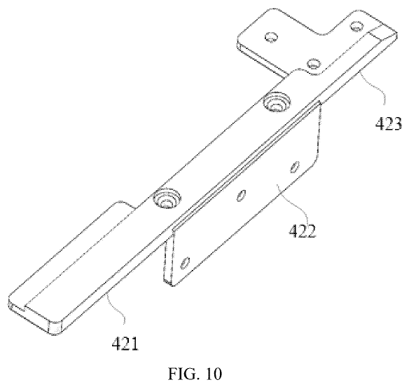

Taking the second connector 420 as an example, as shown in FIG. 10, the second connector 420 includes a second connecting head 421, a second connecting middle portion 422, and a second connecting tail 423, which are sequentially connected. The second connecting head 421 has a sixth region, the second connecting middle portion 422 has a fifth region, and the second connecting tail 423 has a fourth region. The fourth, fifth, and sixth regions may not be on the same plane.

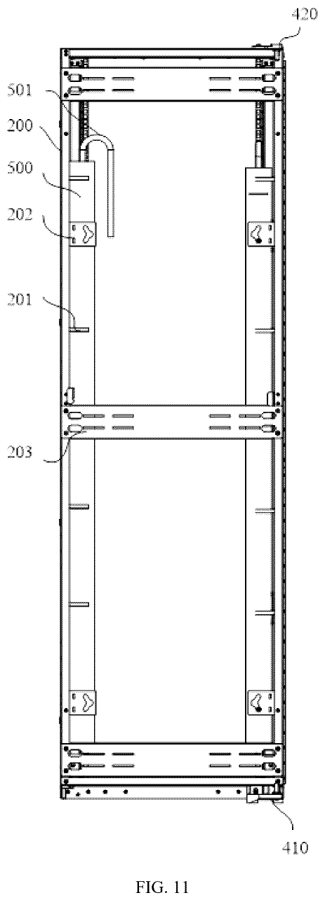

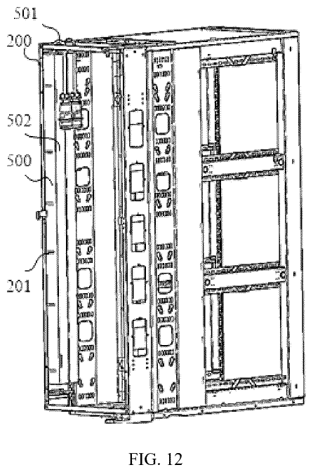

In certain embodiments, as shown in FIGS. 11, 12, and 13, the side panel 204 of the expansion assembly 200 includes a positioning assembly for positioning a functional component 500. The functional component 500 is used to connect to the server and is at least partially located in the second cavity. The dimensions of the second cavity at the junction with the first cavity are adapted to meet the bending radius of the connecting pipes and cables to the server; the cable bend of the connecting cable may pass through the opening structure.

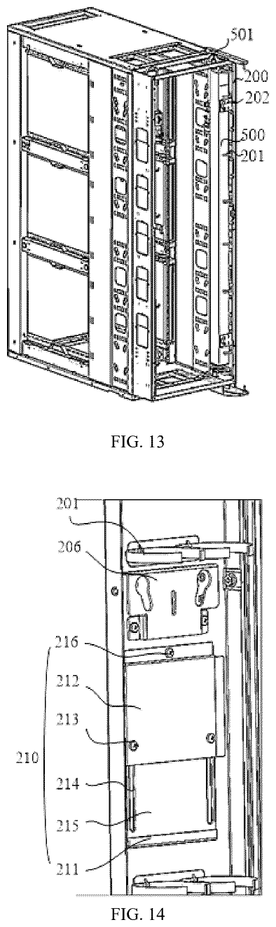

As shown in FIGS. 12 and 13, the functional component 500 has a functional surface 502. The functional component 500 may be installed in the positioning assembly in a first posture or a second posture, so that the installation posture of the functional component 500 may be adjusted. In certain embodiments, additional or rationalized cable management fixing points may be set.

The functional component 500 is mounted at the first posture on the positioning assembly on one side panel 204 of the expansion assembly 200, with its functional surface 502 facing the other side panel 204 of the expansion assembly 200. The functional component 500 is mounted at the second posture on the positioning assembly on the side panel 204 of the expansion assembly 200, with its functional surface 502 facing the first cavity.

The functional component 500 may be a component with corresponding functions, such as a PDU (Power Distribution Unit), and has a functional surface 502. In certain embodiments where the functional component 500 is a PDU, the functional surface 502 may be a socket surface.

In certain embodiments, both side panels 204 of the expansion assembly 200 have a first opening structure 210 and a positioning assembly.

As shown in FIG. 12, in certain embodiments, the positioning assembly has at least two mounting locations for mounting a single functional component 500. Two functional components 500 are mounted at the first posture on the two mounting locations of the positioning assembly. When the two functional components 500 are installed at the first posture, the functional surfaces 502 of the two functional components 500 face the same direction. That is, both functional components 500 are connected to one side panel 204 of the expansion assembly 200, and the functional surfaces 502 face the other side panel 204 of the expansion assembly 200. An operator may be positioned between one side panel 204 of the expansion assembly 200 and the other side panel 204 of the expansion assembly 200, and operate the functional surfaces 502 of the functional components 500 while facing the one side panel 204 of the expansion assembly 200. At the first posture, the facing surfaces of the two functional components 500 are non-functional surfaces, which may reduce the distance between the two functional components 500 and even allow the two functional components 500 to contact each other, without obstructing the functional surfaces 502. This improves the structural compactness of the two functional components 500 and reduces the space occupied.

As shown in FIG. 13, in certain embodiments, a single functional component 500 is installed on both sides of the expansion assembly 200. A single functional component 500 is installed in one mounting location on the positioning assembly, with the functional component 500 mounted at the second posture. When the single functional component 500 is installed at the first posture, the two functional components 500 are respectively connected to the two side panels of the expansion assembly 200, with the functional surfaces 502 of both functional components 500 facing the first cavity. This facilitates connection between the devices (such as servers) located in the first cavity and the functional surfaces 502 and prevents excessive bending of the cables connecting the devices in the first cavity to the functional components 500.

In certain embodiments, the cable bend 501 of the connecting cable of the functional component 500 may pass through the second opening structure 220.

The positioning assembly may include a first positioning component 201, which may surround or partially surround the outer periphery of the functional component 500 to achieve positioning of the functional component 500. In certain embodiments, the first positioning component 201 may be a tie strap or a clamp. The tie strap may be fastened by tying the ends together or by providing a connection such as Velcro or snap fasteners at the ends.

The positioning assembly may also include a positioning member connected to one surface of the functional component 500, with the position of the positioning member adjusted accordingly based on the installation posture of the functional component 500.

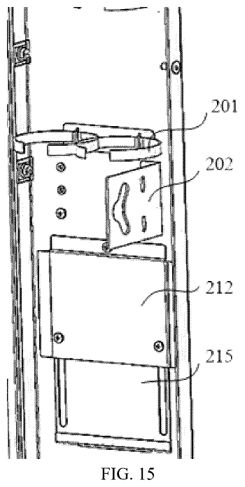

In certain embodiments, as shown in FIGS. 12 and 14, the surface of the functional component 500 facing away from the functional surface 502 has a positioning and mating structure. When the functional component 500 is installed in the positioning assembly at the first posture, the second positioning component 206 is parallel to and connected to the sidewall 204 of the expansion assembly 200, and the second positioning component 206 is connected to the positioning and mating structure. The positioning and mating structure may be a raised portion, and the second positioning component 206 has a retaining hole that engages with the raised portion.

In certain embodiments, as shown in FIGS. 13 and 15, the surface of the functional component 500 facing away from the functional surface 502 has a positioning and mating structure. When the functional component 500 is installed in the positioning assembly at the second posture, the third positioning component 202 is perpendicular to and connected to the side wall 204 of the expansion assembly 200, and the third positioning component 202 is connected to the positioning and mating structure. The positioning and mating structure may be a raised portion, and the third positioning component 202 has a retaining hole that engages with the raised portion.

Various embodiments are described, with each embodiment focusing on the differences from the other embodiments. Reference may be made to the common and similar parts between the various embodiments.

The above description of the disclosed embodiments is intended to enable one skilled in the technical field to implement or use the present disclosure. Various modifications to these embodiments are readily apparent to one skilled in the technical field, and the general principles defined herein may be implemented in other embodiments without departing from the spirit or scope of the present disclosure. Therefore, the present disclosure is not limited to certain embodiments shown herein but is intended to be accorded the widest scope consistent with the principles and novel features disclosed herein.

What is claimed is:

1. A cabinet structure, comprising:
a cabinet body, defining a first cavity to receive servers;
an expansion assembly, contacting the cabinet body and defining a second cavity in communication with the first cavity; and
a water-cooling door, to remove heat from the first and second cavities through heat transfer.

2. The cabinet structure of claim 1, wherein the expansion assembly includes an opening structure for routing cables.

3. The cabinet structure of claim 2, wherein the opening structure includes an adjustable opening area.

4. The cabinet structure of claim 1, further comprising:
a connecting assembly, wherein a first end of the connecting assembly contacts the cabinet body, and a second end of the connecting assembly contacts the expansion assembly.

5. The cabinet structure of claim 1, wherein the expansion assembly is positioned between the water-cooling door and the cabinet body.

6. The cabinet structure of claim 2, wherein the opening structure includes one or both of:
a first opening structure positioned on a side panel of the expansion assembly; and
a second opening structure positioned on a top panel of the expansion assembly.

7. The cabinet structure of claim 6, wherein a size of the first opening structure or a size of the second opening structure is adjustable.

8. The cabinet structure of claim 6, wherein the first opening structure includes a first opening and a first shielding group, and a size of the first opening is adjustable when the first shielding group shields at least a portion of the first opening by moving from one position to another position relative to the first opening, and wherein the second opening structure includes a second opening and a second shielding group, and a size of the second opening is adjustable when the second shielding group shields at least a portion of the second opening by moving from one position to another position relative to the first opening.

9. The cabinet structure of claim 8, wherein the first shielding group includes a first shielding plate and a first sliding plate different from the first shielding plate.

10. The cabinet structure of claim 8, wherein the second shielding group includes a second shielding plate and a second sliding plate different from the second shielding plate.

11. A method of forming a cabinet structure, the method comprising:
providing a cabinet body, an expansion assembly, and a water-cooling door, wherein the cabinet body is configured to define a first cavity to receive servers, the expansion assembly is configured to contact the cabinet body and define a second cavity in communication with the first cavity, and the water-cooling door is configured to remove heat from the first and second cavities through heat transfer.

12. The method of claim 11, wherein the expansion assembly is configured to include an opening structure for routing cables.

13. The method of claim 11, wherein the opening structure is configured to include an adjustable opening area.

14. The method of claim 11, further comprising:
providing a connecting assembly, wherein a first end of the connecting assembly is configured to contact the cabinet body, and a second end of the connecting assembly is configured to contact the expansion assembly.

15. The method of claim 11, wherein the expansion assembly is configured to be positioned between the water-cooling door and the cabinet body.

16. The method of claim 12, wherein the opening structure is configured to include one or both of:
a first opening structure positioned on a side panel of the expansion assembly; and
a second opening structure positioned on a top panel of the expansion assembly.

17. The method of claim 16, wherein a size of the first opening structure or a size of the second opening structure is configured to be adjustable.

18. The method of claim 16, wherein the first opening structure is configured to include a first opening and a first shielding group, and a size of the first opening is adjustable when the first shielding group shields at least a portion of the first opening by moving from one position to another position relative to the first opening, and wherein the second opening structure is configured to include a second opening and a second shielding group, and a size of the second opening is adjustable when the second shielding group shields at least a portion of the second opening by moving from one position to another position relative to the first opening.

19. The method of claim 17, wherein the first shielding group is configured to include a first shielding plate and a first sliding plate different from the first shielding plate, and wherein the second shielding group is configured to include a second shielding plate and a second sliding plate different from the second shielding plate.

20. A cabinet structure, comprising:
a cabinet body, defining a first cavity to receive servers;
an expansion assembly, contacting the cabinet body and defining a second cavity in communication with the first cavity;
a water-cooling door, to remove heat from the first and second cavities through heat transfer; and
a connecting assembly, contacting the cabinet body, the expansion assembly, and the water-cooling door.
